(19) United States
(12) Patent Application Publication
(10) Pub. No.: US 2011/0012809 A1
(43) Pub. Date: Jan. 20, 2011

(54) RF PRINTING RECTIFIER USING ROLL TO ROLL PRINTING METHOD

(76) Inventors: Gyou Jin Cho, Suncheon (KR); Jae Young Kim, Suncheon (KR); Nam Soo Lim, Suncheon (KR); Jun Soek Kim, Suncheon (KR); Hwi Won Kang, Suncheon (KR); Chae Min Lim, Suncheon (KR)

Correspondence Address: IPLA P.A., 3550 WILSHIRE BLVD., 17TH FLOOR, LOS ANGELES, CA, 90010, US

(21) Appl. No.: 12/933,570

(22) PCT Filed: Apr. 3, 2008
(86) PCT No.: PCT/KR08/06509

§ 371 Date: Sep. 20, 2010

(30) Foreign Application Priority Data
Apr. 3, 2008 (KR) 10-2008-0031339

(51) Int. Cl. H01Q 1/00; H01L 21/18

(52) U.S. Cl. 343/904; 438/57; 977/762; 977/932; 257/E21.085

(57) ABSTRACT

Disclosed herein is an RF printed rectifier manufactured using a roll to roll printing process, comprising: a printed antenna manufactured using conductive ink through the roll to roll printing process; a printed diode manufactured using the conductive ink through the roll to roll printing process; and a printed capacitor manufactured using the conductive ink through the roll to roll printing process, wherein an alternating current is input through the printed antenna, and a direct current is output through the printed diode and capacitor.

### TECHNICAL FIELD

The present invention relates to a radio frequency (RF) printed rectifier using a roll to roll printing process and a method of manufacturing the same, and, more particularly, to a radio frequency (RF) printed rectifier manufactured using conductive ink, semiconductor ink, dielectric ink and conductor ink through a roll to roll printing process and a method of manufacturing the same.

### BACKGROUND ART

With the growth of the market for digital household electric appliances such as mobile phones, digital cameras, DVDs, PDPs, LCDs and the like, requirements for an apparatus and a process for manufacturing semiconductors and other precise electronic parts are increasingly changing. In addition to the fields of ICs, electronic parts and displays, even in the energy fields of donor-acceptor type organic solar cells, dye-sensitized solar cells including titanium oxides, zinc oxides and the like, and fuel cells, research into simplifying a production process and reducing process costs are undergoing as new products are gradually put to practical use.

Unlike a conventional method of producing electronic products, a technology of manufacturing printed electronic devices is a technology which applies the printing technology which has been used to fabricate printed materials such as newspapers, magazines, posters and the like to the manufacture of electronic parts. Technologies of manufacturing a radio frequency identification (RFID) tag using the technology of manufacturing printed electronic devices are being developed.

In a conventional RFID tag, RF power supplied from a reader is induced into an alternating voltage using an inductively-coupled type antenna, and the induced alternating voltage is converted into a direct voltage using a silicon-based rectifier and capacitor, thereby supplying power necessary for the operation of the RFID tag. A combination of the antenna and rectifier is referred to as “a rectenna”.

A high frequency (HF) antenna used in an RFID tag having a frequency band of 13.56 MHz is often manufactured by etching copper foil. Further, since a crystalline silicon-based rectifier includes silicon diodes and capacitors and exhibits high DC conversion ratio at a frequency band ranging from low frequency (LF) to ultra high frequency (UHF), the crystalline silicon-based rectifier is chiefly used as an energy supply source for most of the hand RFID tags.

However, this rectifier, based on silicon and inorganic oxides, is problematic in that it is less compatible with the manufacturing of an ultra low priced printed RFID tag. Thus, a printed rectifier manufactured using a 100% printing technology is required.

### DISCLOSURE OF INVENTION

### Technical Problem

Accordingly, the present invention has been made keeping in mind the above problems occurring in the prior art, and an object of the present invention is to provide an RF printed rectifier which is manufactured by a roll to roll printing process and which can supply a direct voltage of 10 V or more through an alternating voltage having a frequency of 13.56 MHz.

Another object of the present invention is to provide a method of manufacturing a printed diode and a printed capacitor necessarily used to manufacture the RF printed rectifier.

Still another object of the present invention is to provide conductive ink, semiconductor ink, dielectric ink and conductor ink which are used to manufacture the RF printed rectifier.

### Technical Solution

In order to accomplish the above objects, an aspect of the present invention provides an RF printed rectifier manufactured using a roll to roll printing process, including: a printed antenna manufactured using conductive ink through the roll to roll printing process; a printed diode manufactured using the conductive ink through the roll to roll printing process; and a printed capacitor manufactured using the conductive ink through the roll to roll printing process, wherein an alternating current is input through the printed antenna, and a direct current is output through the printed diode and capacitor.

In the RF printed rectifier, the conductive ink includes silver nano ink, and the silver nano ink may contain 10˜70 wt % of silver and may have a viscosity of 300˜1000 cP (centi-Poise).

Further, the printed diode may be manufactured using semiconductor ink prepared by stirring a semiconductor nanowire and a polymer material or using conductor ink having a low work function which can form a rectifying contact (Schottky contact) with the semiconductor ink due to the difference in work function between the conductor ink and a semiconductor material, in addition to being manufactured using the conductive ink.

Further, the semiconductor nanowire may be selected from among a ZnO nanowire, GaAs nanowire, InAs nanowire, and Si nanowire.

Further, the ZnO nanowire may be prepared by synthesizing zinc (Zn) acetate, cobalt (Co) acetate and trioctylamine at a temperature of 200˜500° C. and a pressure of 1˜400 atm.

Further, the GaAs nanowire may be prepared by synthesizing As(SiMe₃)₃, Bi Nanocrystal, toluene, oleic acid, trioctylamine and GaCl₃ under a nitrogen atmosphere.

Further, the InAs nanowire may be prepared by synthesizing As(SiMe₃)₃, Bi Nanocrystal, toluene, oleic acid, trioctylamine and InCl₃ under a nitrogen atmosphere.

Further, the Si nanowire may be prepared by synthesizing monophenylsilane and gold nanoparticles coated with dodecanthiol.

Further, the polymer material may be selected from among polyaniline, PEDOT, polypyrrole, MEH-PPV, and P3HT.

Further, the conductor ink may be selected from among Ag—Cs alloy, Ag—Al alloy, Ag—Mg alloy, and Ag—Ca alloy.

Further, the printed capacitor may be manufactured using dielectric ink prepared by stirring an inorganic substance and a polymer material, in addition to being manufactured using the conductive ink.

Further, the polymer material may be selected from among acrylate polymers, epoxy polymers, and phenol polymers.

Furthermore, the inorganic substance may be selected from among TiO₂, SiO₂, Al₂O₃, Nb₂O₅, BaTiO₃, Si₃N₄, and Ta₂O₅.

In order to accomplish the above objects, another aspect of the present invention provides a method of manufacturing an RF printed rectifier using a roll to roll printing process, including the steps of: manufacturing a printed antenna using conductive ink through the roll to roll printing process; manufacturing a plurality of printed diodes using the conductive ink through the roll to roll printing process; and manufacturing a plurality of printed capacitors using the conductive ink through the roll to roll printing process, wherein the RF printed rectifier is manufactured such that an alternating current is input through the printed antenna, and a direct current is output through the printed diode and capacitor.

In the method, the step of manufacturing a plurality of printed diodes may include: printing a lower electrode using the conductive ink through the roll to roll printing process; printing a semiconductor layer on the lower electrode using semiconductor ink prepared by stirring a semiconductor nanowire and a polymer material; and printing an upper electrode using conductor ink having a low work function which can form a rectifying contact (Schottky contact) with the semiconductor ink due to the difference in work function between the conductor ink and a semiconductor material.

Further, the step of manufacturing a plurality of printed capacitors may include: printing a lower electrode using the conductive ink through the roll to roll printing process; printing a dielectric layer on the lower electrode using dielectric ink prepared by stirring an inorganic substance and a polymer material; and printing an upper electrode on the dielectric layer using the conductive ink through the roll to roll printing process.

### ADVANTAGEOUS EFFECTS

Since the RF printed rectifier according to the present invention is manufactured using a roll to roll printing process and a 100% printing process, a direct voltage of 10 V or more can be stably rectified at a high frequency (HF) band, process costs are low, and process efficiency is very high.

### BRIEF DESCRIPTION OF DRAWINGS

The above and other objects, features and advantages of the present invention will be more clearly understood from the following detailed description taken in conjunction with the accompanying drawings, in which:

FIG. 1 shows a voltage doubler circuit diagram of an RF printed rectifier according to an embodiment of the present invention;

FIG. 2 shows a printed antenna having a HF band according to an embodiment of the present invention;

FIG. 3 is a scanning electron microscope (SEM) photograph of zinc oxide nanowires according to an embodiment of the present invention;

FIG. 4 shows a voltage doubler circuit according to another embodiment of the present invention;

FIG. 5 is a graph showing the results of X-ray diffraction (XRD) analysis of zinc oxide nanowires according to an embodiment of the present invention;

FIG. 6 shows a first antenna having a HF band (13.56 MHz), which is printed using a roll to roll printing process, according to an embodiment of the present invention;

FIG. 7 shows a second antenna having a HF band (13.56 MHz), which is printed using a roll to roll printing process, according to an embodiment of the present invention;

*FIG. 8 is a voltage-current graph of a printed diode according to an embodiment of the present invention;

FIG. 9 is a graph showing the direct voltage rectified characteristics of a printed diode according to an embodiment of the present invention; and

FIG. 10 is a graph showing the direct voltage rectified characteristics of a RF printed rectifier according to an embodiment of the present invention.

### DESCRIPTION OF THE ELEMENTS IN THE DRAWINGS

100: printed antenna
201, 202, 203: printed diode
301, 302, 303: printed capacitor

### BEST MODE FOR CARRYING OUT THE INVENTION

As the terms used in the present invention, if possible, general terms commonly used in the related fields are selected. However, in specific cases, there are terms arbitrarily selected by the applicant of the present invention, and, in this case, the meanings of the terms are described in the corresponding detailed description section of the present invention. Therefore, the present invention must be understood by the meanings of the terms, not by the simple definitions of the terms.

Hereinafter, preferred embodiments of the present invention will be described in detail with reference to the accompanying drawings. However, the feature and scope of the invention is not limited thereto.

In the present invention, a roll to roll printing process means a printing process in which a flexible copper clad laminate (FCCL) is used in a state in which it is directly wound on a rotating roll without cutting the CCL.

In the present invention, conductive ink for a roll to roll printer includes silver nano ink used for antennas and electrodes, and is prepared using silver nano gel. The silver nano ink includes 10˜70 wt %, preferably, 20˜50 wt % of silver. Further, the silver nano ink has a viscosity of 300˜1000 cP, preferably, 400˜500 cP. Furthermore, in the case of the silver nano gel, the silver nano ink is prepared using the silver nano gel disclosed in Korean Patent Application No. 10-2007-0079897. In order to realize the antenna performance of an RFID tag, the conductive ink has a conductivity of 0.8˜15 mΩ/□/mil, preferably, 0.8˜5 mΩ/□/mil.

In the present invention, a printed antenna, shown in FIG. 2, is a 100% printed antenna manufactured using silver nano ink as a raw material through a roll to roll gravure printing process, and is used to supply alternating-current power to an RFID tag having a frequency of 13.56 MHz.

In the present invention, a semiconductor nanowire, shown in FIG. 3, is an inorganic semiconductor nanowire prepared at high temperature and pressure using a precursor of a semiconductor, such as Si, Ga, As, In, Zn or the like. Examples of doping materials include Co, B, Al, P, Ag, In, and Ga.

In the present invention, semiconductor ink is prepared by mixing a semiconductor nanowire made of such as Si, ZnO, GaAS, or InAs nanowire with a polymer material such as polyaniline, PEDOT, polypyrrole, MEH-PPV or P3HT.

In the present invention, dielectric ink is hybrid ink of an inorganic substance and a polymer material. The dielectric ink must have a dielectric constant of 10 or more, and must have high adhesion to a substrate and excellent spreadability. Examples of the polymer material include acrylate polymers such as polyimide and polymethacrylate, epoxy polymers such as epoxy resins and polyester, and phenol polymers such as polyvinyl phenol and phenoxy resin. Further, Examples of the inorganic substance include TiO₂, SiO₂, Al₂O₃, Nb₂O₅, BaTiO₃, Si₃N₄, Ta₂O₅ and the like.

In the present invention, conductor ink having low work function is a material which can form a rectifying contact (Schottky contact) with the semiconductor ink using the difference in work function between the conductor ink and a semiconductor material, and is a conductor for printing a primary electrode, having lower work function than silver. The examples of the conductor ink include Ag—Cs, Ag—Al, Ag—Mg, and Ag—Ca alloys.

In the present invention, printed diodes 201, 202 and 203 are devices manufactured by forming a lower electrode on a plastic film using silver nano ink for roll to roll printing, printing semiconductor ink on the silver lower electrode using a roll to roll printing process or a pad printing process, and then printing metal ink having a low work function thereon using a roll to roll printing process or a pad printing process to form an upper electrode. Each of the manufactured diodes has a rectification ratio of 103˜104, and can rectify direct voltage of 5 V or more at a HF band in a state of alternating input voltage of 20 V.

In the present invention, printed capacitors 301, 302 and 303 are devices manufactured by forming a lower electrode using silver nano ink through a roll to roll printing process, printing dielectric ink on the silver lower electrode, and then further forming a lower electrode using silver nano ink to form an upper electrode. Each of the manufactured capacitors generally has a capacitance of 0.01˜10 nF, although its capacitance is changed depending on its area. The capacitance per unit area of each of the manufactured capacitors is generally 0.1˜100 nF/cm².

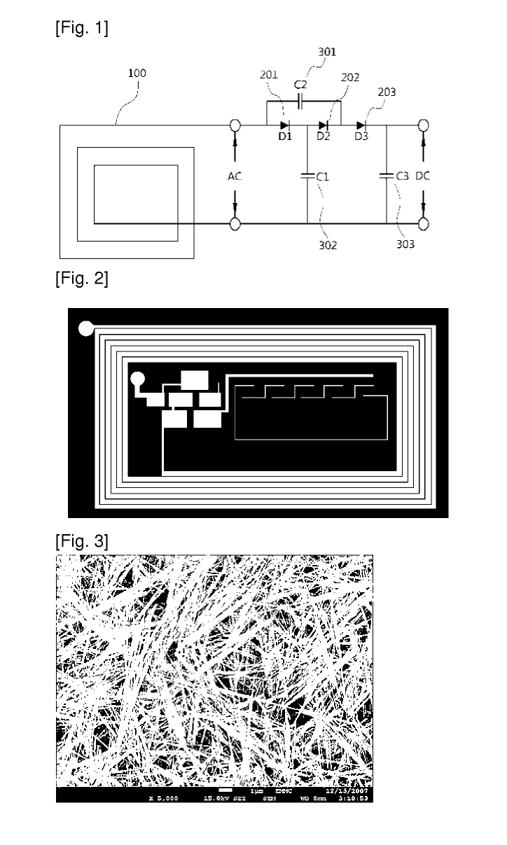

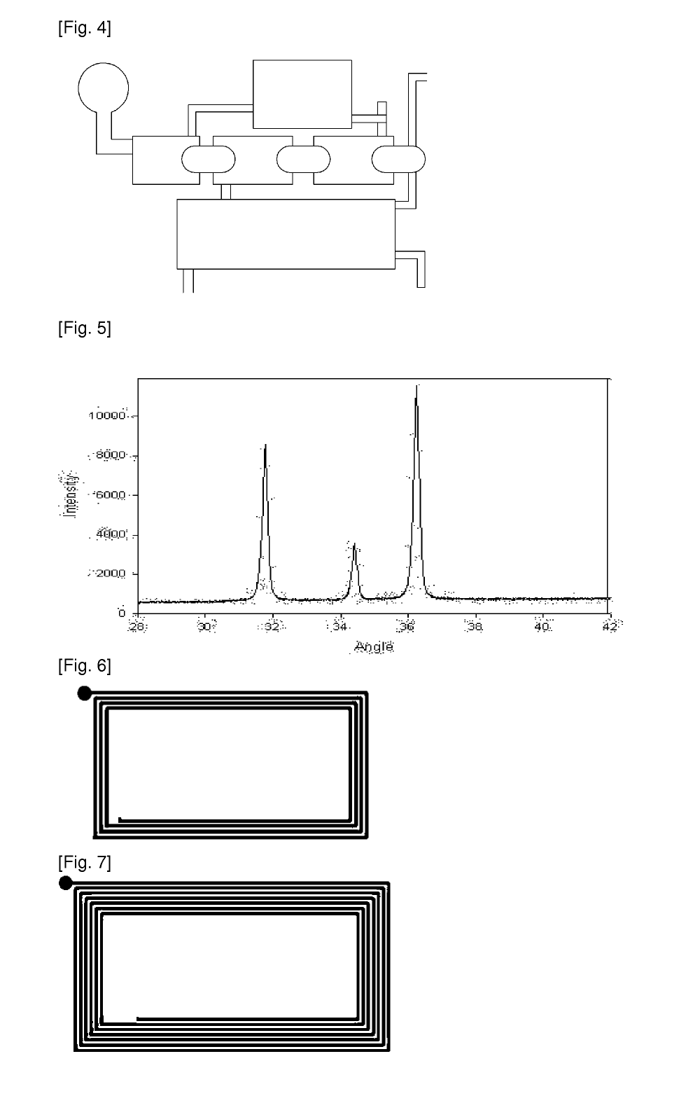

In the present invention, an RF printed circuit is a printed rectifier which can be used as a voltage doubler circuit. As shown in FIG. 1, the RF printed circuit includes at least one printed antenna 100, a plurality of printed diodes 201, 202 and 203 (for example, three printed diodes), a plurality of printed capacitors 301, 302 and 303 (for example, three printed capacitors), and wires manufactured by printing silver nano ink. The printed rectifier according to the present invention may be manufactured the same as the voltage doubler circuit shown in FIG. 4, but is not limited thereto. The RF printed rectifier can rectify direct voltage of 10 V or more at a HF band in a state of alternating input voltage of 20 V.

### MODE FOR THE INVENTION

Hereinafter, the present invention will be described in more detail with reference to the following Examples.

A better understanding of the present invention may be obtained through the following examples which are set forth to illustrate, but are not to be construed as the limit of the present invention.

### Example 1

Zinc acetate (2.66 mol) and cobalt acetate (0.13 mol) were put into a reactor, trioctylamine (25 ml) was added thereto to form a mixture, and then the mixture was stirred in a supercritical state at a reaction temperature of 310° C. for 30 minutes to form a green material on the wall surface of the reactor. This green material was a zinc oxide nanowire doped with cobalt. Subsequently, the green zinc oxide nanowire is added and dispersed in ethanol to form a dispersion solution, and then a solvent and a finally-synthesized zinc oxide nanowire doped with cobalt were separated from the dispersion solution using a centrifugal separator. FIG. 3 is a scanning electron microscope photograph of the synthesized zinc oxide nanowire.

FIG. 5 is a graph showing the results of X-ray diffraction analysis of the zinc oxide nanowire. The separated zinc oxide nanowire doped with cobalt was powdered. The separated zinc oxide nanowire doped with cobalt was mixed with polyaniline at a mixing ratio of 1:5 and then stirred to prepare ink.

### Example 2

After Bi nanocrystals in which As(SiMe₃)₃ and GaCl₃ are dissolved in trioctylamine (TOA) were provided, Bi(III)2-ethylhexanoate was dissolved in dioctyl ether and trioctylphosphine (TOP) to form a mixed solution, and then NaBH4 dissolved in ethylenediamine added to the mixed solution, and thus Bi nanocrystals were deposited by an insoluble solvent. In order to grow the deposited Bi nanocrystals into GaAs nanowires, reactants of As(SiMe₃)₃ 8.6 μL, Bi nanocrystal 1.7 mg, toluene 300 μL, oleic acid 24 Ml and Trioctly amine 850 μL were added to a hot solution (340° C.) in which GaCl₃ 14.3 mg and myristic acid 5.6 mg were dissolved in trioctylamine (TOA) 2.5 mL and then stirred in a glove box charged with nitrogen. In this case, the temperature of the resulting solution was decreased to a temperature of 40° C., but the resulting solution was heated to a temperature of 340° C. and then further stirred for 5 minutes to grow GaAs nanowires.

### Example 3

InCl₃ 18 mg, As(SiMe₃)₃ 8.6 μL, Bi nanocrystal 1.7 mg, toluene 300 μL, oleic acid 24 μL and trioctyl amine 850 μL were added to a hot solution (340° C.) in which myristic acid 5.6 mg was dissolved in trioctylamine (TOA) 2.5 mL and then stirred in a glove box charged with nitrogen. In this case, the temperature of the resulting solution was decreased to a temperature of 40° C., but the resulting solution was heated to a temperature of 340° C. and then further stirred for 5 minutes to grow InAs nanowires.

### Example 4

Monophenylsilane (272 mM) was dissolved in benzene in a glove box, and then gold nanoparticles (1 mg/mL) coated with dodecanthiol were added thereto to form a mixed solution. In this case, the mixing ratio of gold to silicon was 1:1000. First, when the solution was put into a reactor at a flow rate of 0.5 mL/min in a state in which the supercritical pressure of the reactor was maintained at 3.4 MPa and then heated to a supercritical temperature of 460° C., the pressure of the reactor was increased to 6.9 MPa. At this time, when the reaction was completed and thus the temperature and pressure of the reactor reached room temperature and atmospheric pressure, respectively, chloroform was added to the reactor and then dispersed to obtain silicon nanowires.

### Example 5

Cs(CH₃COO)₂ (0.1 g), phenylhydrazine (0.2 mL) and silver nano gel (1 g) were added to a solution (3 mL) in which non-doped polyaniline is dissolved in N-methyl-2-pyrrolidone, and then dispersed to prepare ink. The prepared ink has a conductivity of 2˜50 mΩ/□/mil, and has a work function lower than that of the conductive ink for a roll to roll printer.

### Example 6

Different patterned roll to roll antennas, shown in FIGS. 6 and 7, were manufactured using the conductive ink for a roll to roll printer through a gravure printing process, and then their characteristics were analyzed. The results thereof are given in Table 1 below

TABLE 1

| | | | | Induced alternating |
|---|---|---|---|---|
| | | | Resistance | voltage |
| Pattern | Turn number | Length [mm] | [Ω] | [V] |
| FIG. 6 | 3.8 | 760 | 40~140 | 10~17 |
| FIG. 7 | 6.8 | 1460 | 100~240 | 28-30 |

### Example 7

A lower electrode was formed on a PET film at an area of 2˜100 mm² using conductive ink for a roll to roll printer using a gravure printer, a semiconductor layer was formed on the lower electrode at an area of 1˜80 mm² using the ZnO semiconductor ink prepared in Example 1 and then sintered at a temperature of 80˜150° C. for 10˜60 minutes, and then an upper electrode was formed on the semiconductor layer at an area of 1˜80 mm² using conductor ink having a low work function, thereby manufacturing printed diodes.

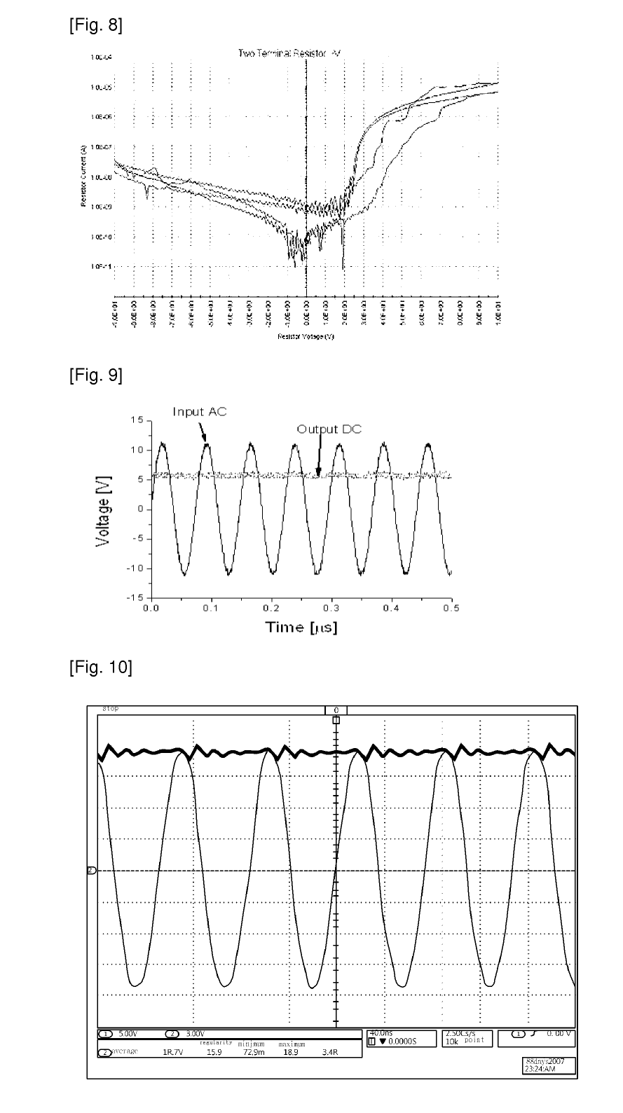

Each of the manufactured diodes has a rectification ratio of 103˜104, as shown in FIG. 8, and can stably rectify direct voltage of 3˜6 V at a HF band, as shown in FIG. 9.

### Example 8

A lower electrode was formed at an area of 1˜100 mm² using conductive ink through a roll to roll gravure printing process, and then an upper electrode was formed on the lower electrode at an area of 1˜90 mm² using dielectric ink through a roll to roll gravure printing process, thereby manufacturing printed capacitors having a capacitance of 0.01˜10 nF.

### Example 9

The printed antenna, printed diodes and printed capacitors manufactured in the respective Example 3, Example 4 and Example 5 were printed on a PET film, as the RF printed rectifier circuit shown in FIG. 1, and wires are printed thereon using silver nano ink, thereby manufacturing an RF printed rectifier (voltage doubler circuit shown in FIG. 4). As shown in FIG. 10, the RF printed rectifier (voltage doubler circuit) can rectify direct voltage of 10 V or more at a HF band in a state of alternating input voltage of 20 V.

### INDUSTRIAL APPLICABILITY

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Therefore, the scope of the present invention may not be limited to the aforementioned embodiments, and may include the accompanying claims and all technical ideas equivalent to these claims.

1. An RF printed rectifier manufactured using a roll to roll printing process, comprising:
a printed antenna manufactured using conductive ink through the roll to roll printing process;
a printed diode manufactured using the conductive ink through the roll to roll printing process; and
a printed capacitor manufactured using the conductive ink through the roll to roll printing process,
wherein an alternating current is input through the printed antenna, and a direct current is output through the printed diode and capacitor.

2. The RF printed rectifier according to claim 1, wherein the conductive ink includes silver nano ink, and the silver nano ink contains 10˜70 wt % of silver and has a viscosity of 300˜1000 cP.

3. The RF printed rectifier according to claim 1, wherein the printed diode is manufactured using semiconductor ink prepared by stirring a semiconductor nanowire and a polymer material and conductor ink having a low work function which can form a rectifying contact with the semiconductor ink due to the difference in work function between the conductor ink and a semiconductor material, in addition to the conductive ink.

4. The RF printed rectifier according to claim 3, wherein the semiconductor nanowire is selected from among a ZnO nanowire, GaAs nanowire, InAs nanowire, and Si nanowire.

5. The RF printed rectifier according to claim 4, wherein the ZnO nanowire is prepared by synthesizing zinc (Zn) acetate, cobalt (Co) acetate and trioctylamine at a temperature of 200˜500° C. and a pressure of 1˜400 atm.

6. The RF printed rectifier according to claim 4, wherein the GaAs nanowire is prepared by synthesizing As(SiMe₃)₃, Bi Nanocrystal, toluene, oleic acid, trioctylamine and GaCl₃ under a nitrogen atmosphere.

7. The RF printed rectifier according to claim 4, wherein the InAs nanowire is prepared by synthesizing As(SiMe₃)₃, Bi Nanocrystal, toluene, oleic acid, trioctylamine and InCl₃ under a nitrogen atmosphere.

8. The RF printed rectifier according to claim 4, wherein the Si nanowire is prepared using gold nanoparticles coated with monophenylsilane and dodecanthiol.

9. The RF printed rectifier according to claim 3, wherein the polymer material is selected from among polyaniline, PEDOT, polypyrrole, MEH-PPV, and P3HT.

10. The RF printed rectifier according to claim 3, wherein the conductor ink is selected from among Ag—Cs alloy, Ag—Al alloy, Ag—Mg alloy, and Ag—Ca alloy, which are capable of being made into ink.

11. The RF printed rectifier according to claim 1, wherein the printed capacitor is manufactured using dielectric ink prepared by stirring an inorganic substance and a polymer material, in addition to the conductive ink.

12. The RF printed rectifier according to claim 11, wherein the polymer material is selected from among acrylate polymers, epoxy polymers, and phenol polymers.

13. The RF printed rectifier according to claim 11, wherein the inorganic substance is selected from among TiO₂, SiO₂, Al₂O₃, Nb₂O₅, BaTiO₃, Si₃N₄, and Ta₂O₅.

14. A method of manufacturing an RF printed rectifier using a roll to roll printing process, comprising:
manufacturing a printed antenna using conductive ink through the roll to roll printing process;
manufacturing a plurality of printed diodes using the conductive ink through the roll to roll printing process;
manufacturing a plurality of printed capacitors using the conductive ink through the roll to roll printing process;
printing a wiring for connecting the printed antenna, the plurality of printed diodes and the plurality of printed diodes to each other, using the conductive ink, wherein the RF printed rectifier is manufactured such that an alternating current is input through the printed antenna, and a direct current is output through the printed diode and capacitor.

15. The method of manufacturing an RF printed rectifier according to claim 14, wherein the manufacturing a plurality of printed diodes comprises:
printing a lower electrode using the conductive ink through the roll to roll printing process;
printing a semiconductor layer on the lower electrode using semiconductor ink prepared by stirring a semiconductor nanowire and a polymer material; and
printing an upper electrode using conductor ink having a low work function which can form a rectifying contact with the semiconductor ink due to the difference in work function between the conductor ink and a semiconductor material.

16. The method of manufacturing an RF printed rectifier according to claim 14, wherein the manufacturing a plurality of printed capacitors comprises:
printing a lower electrode using the conductive ink through the roll to roll printing process;
printing a dielectric layer on the lower electrode using dielectric ink prepared by stirring an inorganic substance and a polymer material; and
printing an upper electrode on the dielectric layer using the conductive ink through the roll to roll printing process.
